(19) United States
(12) Patent Application Publication
(10) Pub. No.: US 2016/0124805 A1
(43) Pub. Date: May 5, 2016

(54) NONVOLATILE MEMORY SYSTEM AND DATA RECOVERY METHOD THEREOF

(71) Applicant: SK hynix Inc., Gyeonggi-do (KR)

(72) Inventor: Hyung-Min LEE, Gyeonggi-do (KR)

(21) Appl. No.: 14/676,341

(22) Filed: Apr. 1, 2015

(30) Foreign Application Priority Data
Nov. 3, 2014 (KR) 10-2014-0151144

(51) Int. Cl. G06F 11/10; G11C 29/02; G11C 29/52

(52) U.S. Cl. CPC G06F 11/1068; G11C 29/52; G11C 29/021

(57) ABSTRACT

A nonvolatile memory system includes a nonvolatile memory device including a plurality of memory cells; and a memory controller suitable for recovering normal data based on a recovery read level interval when an error occurs in the normal data read from the memory cells by using a reference read level, wherein the memory controller generates N distribution measurement values by measuring distribution values of threshold voltage levels of the memory cells at N respective distribution read levels, which have a preset read level interval with the reference read level serving as a center, and determines the recovery read level interval through calculating variations of the N distribution measurement values by using a linear equation, where ‘N’ is a natural number equal to or larger than 2.

### CROSS-REFERENCE TO RELATED APPLICATIONS

The present application claims priority of Korean Patent Application No. 10-2014-0151144, filed on Nov. 3, 2014, which is incorporated herein by reference in its entirety.

### BACKGROUND

1. Field

Exemplary embodiments of the present invention relate to a semiconductor design technology and, more particularly, to a data recovery method of a nonvolatile memory device.

2. Description of the Related Art

Semiconductor memory devices included in a data storage system are generally divided into volatile memory devices and nonvolatile memory devices.

A volatile memory device may perform write and read operations at high speed, but data stored therein may be lost when power is blocked. On the other hand, in a nonvolatile memory device, the stored data may be retained even without power. However, write and read speeds thereof are relatively slow. Therefore, to retain the stored data regardless whether there is a constant power source, a nonvolatile memory device is used. A read only memory (ROM), a mask ROM (MROM), a programmable ROM (PROM), an erasable programmable ROM (EPROM), an electrically erasable programmable ROM (EEPROM), a flash memory, a phase change random access memory (PRAM), a magnetic RAM (MRAM), a resistive RAM (RRAM), and a ferroelectric RAM (FRAM) are examples of nonvolatile memory devices. Additionally, flash memory devices may be classified into NOR and NAND types.

Flash memory has advantages of RAM, in that program and erase operations may be freely performed, as well as advantages of ROM, in that the stored data may be retained even without power. Flash memories are widely used as the storage media of portable electronic appliances such as digital cameras, personal digital assistants (PDAs) and an MP3 players. Therefore, reliability of data in memory storage systems is regarded as an important issue.

### SUMMARY

Various embodiments of the present invention are directed to a nonvolatile memory system using a data recovery method capable of achieving high data reliability while minimizing deterioration of performance.

In an embodiment, a nonvolatile memory system may include: a nonvolatile memory device including a plurality of memory cells; and a memory controller suitable for recovering normal data based on a recovery read level interval when an error occurs in the normal data read from the memory cells by using a reference read level, wherein the memory controller generates N distribution measurement values by measuring distribution values of threshold voltage levels of the memory cells at N distribution read levels, which have a preset read level interval with the reference read level serving as a center, and determines the recovery read level interval through calculating variations of the N distribution measurement values by using a linear equation, where ‘N’ is a natural number equal to or greater than 2.

In an embodiment, the memory controller may receive the recovery read level interval, as a read interval of a log likelihood ratio (LLR), and performs a low density parity check (LDPC) for the normal data to recover the normal data.

In an embodiment, the preset read level interval corresponds to K times a minimum read level interval that may be controllable to read data stored in the memory cells, where ‘K’ is a natural number equal to or greater than 2.

In an embodiment, the memory controller, during an error correcting operation mode, may alternately read N distribution data and N measurement data from the memory cells by alternately using the N distribution read levels and N measurement read levels, which are respectively close to the N distribution read levels with the minimum read level interval, compares the N distribution data and the N measurement data to generate differences thereof as the N distribution measurement values.

In an embodiment, the memory controller, during the error correcting operation mode, may generate N distribution variation values by dividing the respective N distribution measurement values by the minimum read level interval of K times for comparting the preset read level interval, and determines an interval between read levels corresponding to level value intercepts in both directions from the reference read level serving as a center, as the recovery read level interval, by extending variations of the respective N distribution variation values by using a linear equation.

In an embodiment, a nonvolatile memory system may further include: a read operation unit suitable for generating the reference read level, the N distribution read levels or the N measurement read levels based on a level control signal, and reading the data of the memory cells by using the read levels as a reference.

In an embodiment, the memory controller may include: a signal generation unit suitable for generating the level control signal with a value for controlling the normal data read from the read operation unit, outside the error correcting operation mode, and generating the level control signal with a value for controlling the N distribution data or the N measurement data read from the read operation unit, during the error correcting operation mode; a counting unit suitable for counting differences of the N distribution data and the N measurement data to generate the N distribution measurement values, during the error correcting operation mode; a storage unit suitable for storing the N distribution measurement values and the N distribution variation values; a first calculation unit suitable for reading the respective N distribution measurement values stored in the storage unit, performing calculations of dividing the respective N distribution measurement values by the minimum read level interval of K times for comparting the preset read level interval, and storing the N distribution variation values generated by the calculations, in the storage unit; a second calculation unit suitable for reading the respective N distribution variation values stored in the storage unit, generating the linear equation by calculating variations of the respective N distribution variation values, finding the read levels corresponding to the level value intercepts by using the linear equation, and determining the interval between the two found read levels, as the recovery read level interval; and an error correcting operation unit suitable for detecting, outside the error correcting operation mode, whether an error occurs in the normal data, and determining whether to enter the error correcting operation mode, and recovering, during the error correcting operation mode, the normal data based on the recovery read level interval.

In an embodiment, the storage unit may include: N first storages for storing the respective N distribution measurement values; and N second storages for storing the respective N distribution variation values.

In an embodiment, the storage unit may include N storages suitable for storing the respective N distribution measurement values based on an operation result of the counting unit, and storing the respective N distribution variation values based on an operation result of the first calculation unit.

In an embodiment, A nonvolatile memory system may include: a nonvolatile memory device suitable for generating N distribution measurement values by measuring distribution values of threshold voltage levels of a plurality of memory cells, by respectively using N distribution read levels, which have a preset read level interval with a reference read level serving as a center, during an error correcting operation mode, where ‘N’ is a natural number equal to or greater than 2; and a memory controller suitable for determining to enter the error correcting operation mode when an error occurs in normal data read from the memory cells by using the reference read level, outside the error correcting operation mode, and recovering the normal data based on a recovery read level interval determined through calculating variations of the respective N distribution measurement values by using a linear equation, during the error correcting operation mode.

In an embodiment, the memory controller may receive the recovery read level interval, as a read interval of an LLR, and performs an LDPC for the normal data to recover the normal data.

In an embodiment, the preset read level interval corresponds to K times a minimum read level interval that may be controllable to read data stored in the memory cells, where ‘K’ is a natural number equal to or greater than 2.

In an embodiment, the nonvolatile memory device, during the error correcting operation mode, may alternately read N distribution data and N measurement data from the memory cells by alternately using the N distribution read levels and N measurement read levels, which are respectively close to the N distribution read levels with the minimum read level interval, and compares the N distribution data and the N measurement data to generate differences thereof as the N distribution measurement values.

In an embodiment, the memory controller, during the error correcting operation mode, may generate N distribution variation values by dividing the respective N distribution measurement values by the minimum read level interval of K times for comparting the preset read level interval, during the error correcting operation mode, and determines an interval between read levels corresponding to level value intercepts in both directions from the reference read level, as the recovery read level interval, by extending variations of the respective N distribution variation values by using the linear equation.

In an embodiment, the nonvolatile memory device may include: a read operation unit suitable for generating the reference read level, the N distribution read levels or the N measurement read levels based on a level control signal, and reading the data of the memory cells, based on using the read levels as a reference; a counting unit suitable for counting differences of the N distribution data and the N measurement data to generate the N distribution measurement values, during the error correcting operation mode; and a first storage unit suitable for storing the N distribution measurement values.

In an embodiment, the memory controller may include: a signal generation unit suitable for generating the level control signal with a value for controlling the normal data read from the read operation unit, outside the error correcting operation mode, and generating the level control signal with a value for controlling the N distribution data or the N measurement data read from the read operation unit, during the error correcting operation mode; a second storage unit suitable for storing the N distribution variation values; a first calculation unit suitable for reading the respective N distribution measurement values stored in the first storage unit, performing calculations of dividing the respective N distribution measurement values by the minimum read level interval of K times for comparting the preset read level interval, and storing the N distribution variation values generated by the calculations, in the second storage unit; a second calculation unit suitable for reading the respective N distribution variation values stored in the second storage unit, generating the linear equation, finding the read levels corresponding to the level value intercepts by using the linear equation generated, and determining the interval between the two found read levels, as the recovery read level interval; and an error correcting operation unit suitable for detecting, outside the error correcting operation mode, whether an error occurs in the normal data, and determining whether to enter the error correcting operation mode, and recovering, during the error correcting operation mode, the normal data based on the recovery read level interval.

In an embodiment, a data recovery method of a nonvolatile memory system including a plurality of memory cells, the method may include: generating N distribution measurement values by measuring distribution values of threshold voltage levels of the memory cells, by respectively using N distribution read levels, which have a preset read level interval with a reference read level serving as a center, during an error correcting operation mode, where ‘N’ is a natural number equal to or greater than 2; determining to enter the error correcting operation mode when an error occurs in normal data read from the memory cells by using the reference read level, outside the error correcting operation mode; and recovering the normal data based on a recovery read level interval determined through calculating variations of the respective N distribution measurement values by using a linear equation, during the error correcting operation mode.

In an embodiment, the recovering of the normal data may include: performing an LDPC for the normal data by using the recovery read level interval as a read interval of an LLR.

In an embodiment, the preset read level interval corresponds to K times a minimum read level interval that may be controllable to read data stored in the memory cells, where ‘K’ is a natural number equal to or greater than 2.

### BRIEF DESCRIPTION OF THE DRAWINGS

FIG. 1 is a diagram illustrating a data processing system including a memory system.

FIG. 2 is a detailed diagram of a memory device in the memory system shown in FIG. 1.

FIG. 3 is a detailed diagram of a memory device including a memory block shown in FIG. 2.

FIGS. 4A to 4C are graphs for describing a low density parity check (LDPC) scheme used for an error correcting function in a nonvolatile memory system.

FIG. 5 is a block diagram illustrating a nonvolatile memory system in accordance with an embodiment of the present invention.

FIG. 6 is a detailed diagram of the nonvolatile memory system shown in FIG. 5.

FIGS. 7A to 7C are graphs for describing an operation of determining a recovery read level interval in accordance with an embodiment of the present invention.

FIG. 8 is a block diagram illustrating a nonvolatile memory system in accordance with an embodiment of the present invention.

FIG. 9 is a detailed diagram of the nonvolatile memory system shown in FIG. 8.

### DETAILED DESCRIPTION

Various embodiments will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts in the various figures and embodiments of the present invention.

It is also noted that in this specification, “connected/coupled” refers to one component not only directly coupling another component, but also indirectly coupling another component through an intermediate component. In addition, a singular form may include a plural form as long as it is not specifically mentioned. It should be readily understood that the meaning of “on” and “over” in the present disclosure should be interpreted in the broadest manner such that “on” means not only “directly on” but also “on” something with an intermediate feature(s) or a layer(s) therebetween, and that “over” means not only directly on top but also on top of something with an intermediate feature(s) or a layer(s) therebetween. When a first layer is referred to as being “on” a second layer or “on” a substrate, it not only refers to where the first layer is formed directly on the second layer or the substrate but also to where a third layer exists between the first layer and the second layer or the substrate.

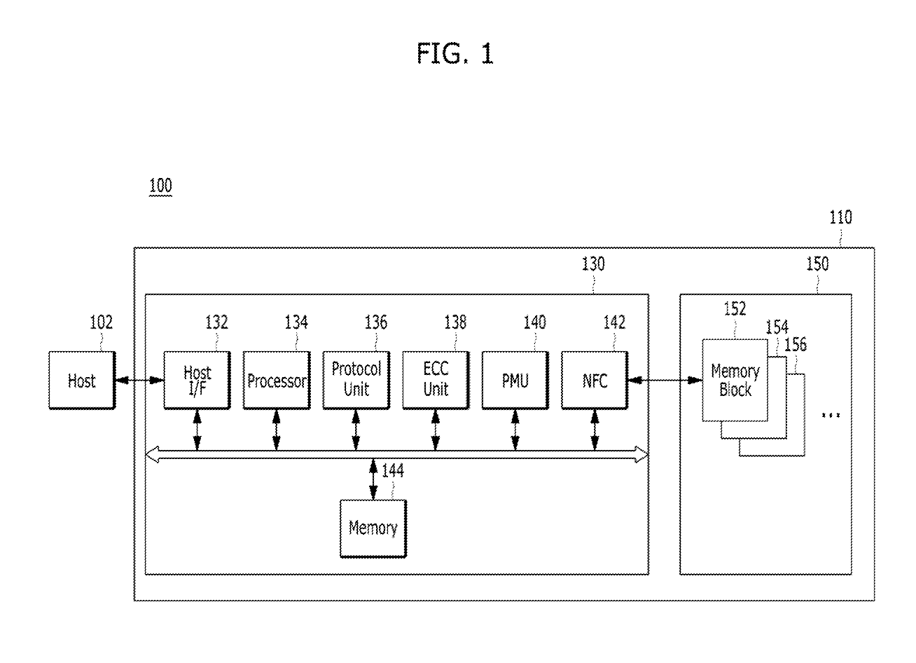

FIG. 1 is a diagram illustrating a data processing system 100 including a memory system.

Referring to FIG. 1, the data processing system 100 may include a host 102 and a memory system 110.

The host 102 includes, for example, a portable electronic device such as a mobile phone, an MP3 player and a laptop computer or an electronic device such as a desktop computer, a game player, a TV and a projector.

The memory system 110 operates in response to a request from the host 102, and in particular, stores data to be accessed by the host 102. In other words, the memory system 110 may be used as a main memory or an auxiliary memory of the host 102. The memory system 110 may be realized as any one of various kinds of storage devices, according to the protocol of a host interface to be electrically coupled with the host 102. For example, the memory system 110 may be realized as any one of various kinds of storage devices such as a solid-state drive (SSD), a multimedia card in the form of an MMC, an eMMC (embedded MMC), an RS-MMC (reduced size MMC) and a micro-MMC, a secure digital card in the form of an SD, a mini-SD and a micro-SD, a universal serial bus (USB) storage device, a universal flash storage (UFS) device, a compact flash (CF) card, a smart media card, a memory stick, and so forth.

The storage devices forming the memory system 110 may be realized as a volatile memory device such as a dynamic random access memory (DRAM) and a static random access memory (SRAM) or a nonvolatile memory device such as a read only memory (ROM), a mask ROM (MROM), a programmable ROM (PROM), an erasable programmable ROM (EPROM), an electrically erasable programmable ROM (EEPROM), an ferroelectric random access memory (FRAM), a phase change RAM (PRAM), a magnetic RAM (MRAM) and a resistive RAM (RRAM).

The memory system 110 includes a memory device 150. The memory device 150 stores data to be accessed by the host 102, and a controller 130 which controls the memory device 150 to store data.

The controller 130 and the memory device 150 may be integrated into one semiconductor device. For instance, the controller 130 and the memory device 150 may be integrated into one semiconductor device to form an SSD. When the memory system 110 is used as the SSD, the operation speed of the host 102, which is electrically coupled with the memory system 110, may be significantly increased.

The controller 130 and the memory device 150 may be integrated into one semiconductor device to form a memory card. For example, the controller 130 and the memory card 150 may be integrated into one semiconductor device to form a memory card such as a personal computer memory card international association (PCMCIA) card, a compact flash (CF) card, a smart media card in the form of an SM and an SMC, a memory stick, a multimedia card in the form of an MMC, an RS-MMC and a micro-MMC, a secure digital card in the form of an SD, a mini-SD, a micro-SD and an SDHC, and a universal flash storage (UFS) device.

Furthermore, the memory system 110 may form a computer, an ultra mobile PC (UMPC), a workstation, a net-book, a personal digital assistant (PDA), a portable computer, a web tablet, a tablet computer, a wireless phone, a mobile phone, a smart phone, an e-book, a portable multimedia player (PMP), a portable game player, a navigation device, a black box, a digital camera, a digital multimedia broadcasting (DMB) player, a 3-dimensional television, a smart television, a digital audio recorder, a digital audio player, a digital picture recorder, a digital picture player, a digital video recorder, a digital video player, a storage for a data center, a device capable of transmitting and receiving information under a wireless environment, one of various electronic devices for a home network, one of various electronic devices for a computer network, one of various electronic devices for a telematics network, an RFID device, or one of various component elements for a computing system.

The memory device 150 may retain stored data even when power is blocked, store the data provided from the host 102, through a write operation, and provide stored data to the host 102, through a read operation. The memory device 150 may include a plurality of memory blocks 152, 154 and 156. Each of the memory blocks 152, 154 and 156 includes a plurality of pages. Each of the pages includes a plurality of memory cells to which a plurality of word lines are electrically coupled. The memory device 150 may be a nonvolatile memory device, for example, a flash memory. The flash memory may have a 3D stack structure.

The controller 130 of the memory system 110 controls the memory device 150 in response to a request from the host 102. For example, the controller 130 provides the data read from the memory device 150, to the host 102, and stores the data provided from the host 102, in the memory device 150. To this end, the controller 130 controls the operations of the memory device 150, such as read, write, program and erase operations.

In detail, the controller 130 may include a host interface (I/F) unit 132, a processor 134, a protocol unit 136, an error correction code (ECC) unit 138, a power management unit (PMU) 140, a NAND flash controller (NFC) 142, and a memory 144.

The host interface unit 132 processes the commands and data of the host 102, and may communicate with the host 102 through at least one of various interface protocols such as a universal serial bus (USB), a multimedia card (MMC), a peripheral component interconnect-express (PCI-E), a serial attached SCSI (SAS), a serial advanced technology attachment (SATA), a parallel advanced technology attachment (PATA), a small computer system interface (SCSI), an enhanced small disk interface (ESDI), and integrated drive electronics (IDE).

The ECC unit 138 detects and corrects an error included in the data read from the memory device 150 when reading the data stored in the memory device 150. That is to say, after performing error correction decoding for the data read from the memory device 150, the ECC unit 138 may determine whether the error correction decoding has succeeded, output an indication signal according to a determination result, and correct an error bit of the read data by using the parity bit generated in an ECC encoding process. The ECC unit 138 may not correct error bits if error bits occur in a number equal to or greater than a threshold number of correctable error bits, and may output an error correction fail signal corresponding to incapability of correcting error bits.

The ECC unit 138 may perform error correction by using a low density parity check (LDPC) code, a Bose, Chaudhuri, and Hocquenghem (BCH) code, a turbo code, a Reed-Solomon code, a convolution code, a recursive systematic code (RSC), a trellis-coded modulation (TCM) or a block coded modulation (BCM). The ECC unit 138 may include all circuits, systems or devices for error correction.

The protocol unit 136 stores and manages protocols for the controller 130 to control the memory device 150 in response to a request from the host 102. The PMU 140 provides and manages power for the controller 130, that is, power for the component elements included in the controller 130.

The NFC 142, as a memory interface which performs interfacing between the controller 130 and the memory device 150 to allow the controller 130 to control the memory device 150 in response to a request from the host 102, generates control signals for the memory device 150 and processes data according to the control of the processor 134, when the memory device 150 is a flash memory (e.g., a NAND flash memory).

The memory 144, as the working memory of the memory system 110 and the controller 130, stores data for driving of the memory system 110 and the controller 130. Specifically, when the controller 130 controls the memory device 150 in response to a request from the host 102. For example, in when the controller 130 provides the data read from the memory device 150 to the host 102, and stores the data provided from the host 102, in the memory device 150, and, to this end, when the controller 130 controls the operations of the memory device 150, such as read, write, program and erase operations, the memory 144 stores data needed to allow such operations to be performed between the controller 130 and the memory device 150.

The memory 144 may be formed of a volatile memory such as a static random access memory (SRAM) or a dynamic random access memory (DRAM). As described above, the memory 144 stores data needed to perform data read and write operations between the host 102 and the memory device 150 and data with which the data read and write operations are performed. For such storage of data, the memory 144 may include a program memory, a data memory, a write buffer, a read buffer, a map buffer, and so forth.

The processor 134 controls the general operations of the memory system 110, and controls a write operation or a read operation for the memory device 150, in response to a write request or a read request from the host 102. The processor 134 drives firmware which is referred to as a flash translation layer (FTL), to control the general operations of the memory system 110. The processor 134 may be formed of a microprocessor or a central processing unit (CPU).

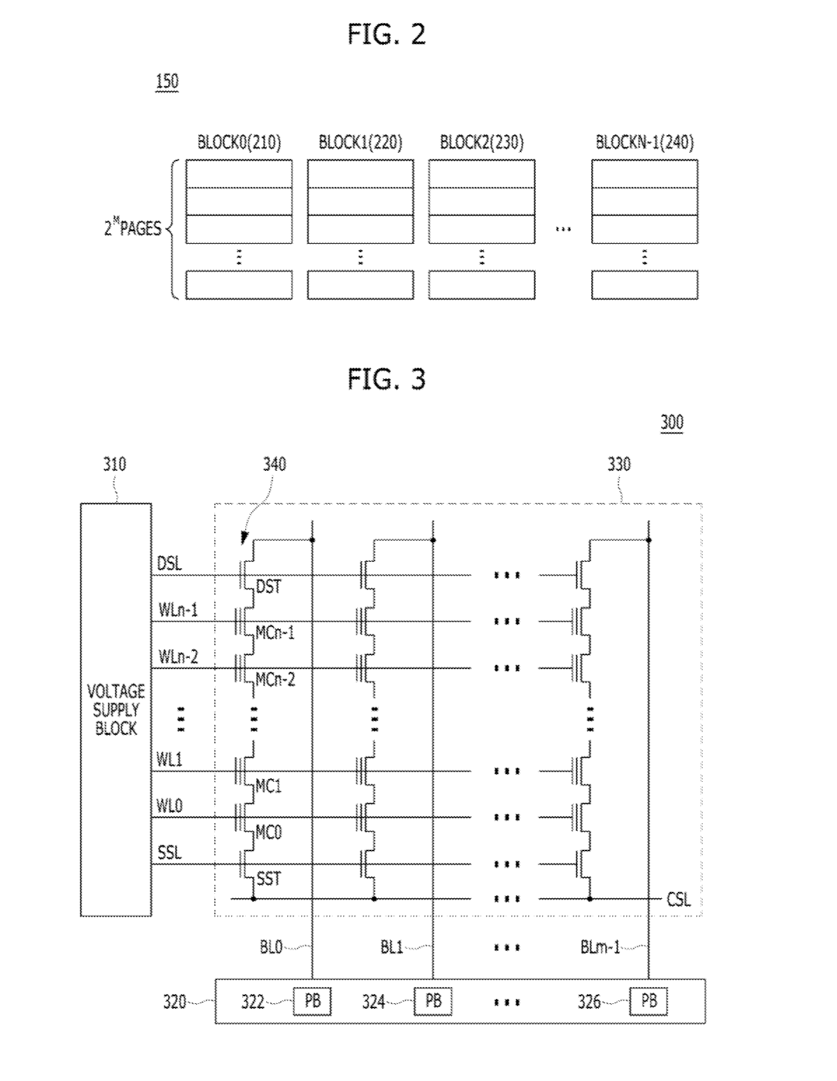

FIG. 2 is a detailed diagram of the memory device 150 shown in FIG. 1.

Referring to FIG. 2, the memory device 150 includes a plurality of memory blocks, for example, a zeroth block (BLOCK0) 210, a first block (BLOCK1) 220, a second block (BLOCK2) 230 and an N−1^{th} block (BLOCKN−1) 240. Each of the blocks 210, 220, 230 and 240 includes a plurality of pages, for example, 2^{M} number of pages (2^{M}PAGES). While it is described for the sake of convenience that each of the memory blocks includes 2^{M} number of pages, it is to be noted that each of the memory blocks may include M number of pages. Each of the pages includes a plurality of memory cells to which a plurality of word lines are electrically coupled.

Each of the memory blocks 210, 220, 230 and 240 stores the data provided from the host device 102, through a write operation, and provides the stored data to the host 102, through a read operation.

FIG. 3 is a detailed diagram a memory device 300 including the memory block shown in FIG. 2. FIG. 3 shows a memory cell array circuit of the memory device 300.

Referring to FIG. 3, in the memory system 110, a memory block 330 of a memory device 300 may include a plurality of cell strings 340 which are electrically coupled to bit lines BL0 to BLm−1, respectively. The cell string 340 of each column may include at least one drain select transistor DST and at least one source select transistor SST. A plurality of memory cell transistors MC0 to MCn−1 may be electrically coupled in series between the select transistors DST and SST. The respective memory cells MC0 to MCn−1 may be configured by multi-level cells (MLC), each of which stores data information of a plurality of bits. The strings 340 may be electrically coupled to corresponding bit lines BL0 to BLm−1, respectively.

For reference, in each of the memory cells MC0 to MCn−1, single bit data may be stored, or multi-bit data of 2 or more bits may be stored. A single level cell (SLC) type nonvolatile memory device, which stores single bit data, has an erased state and a programmed state according to a threshold voltage distribution. A multi-level cell (MLC) type nonvolatile memory device, which stores multi-bit data, has one erased state and a plurality of programmed states according to a threshold voltage distribution. In FIG. 3, ‘DSL’ denotes a drain select line, ‘SSL’ denotes a source select line, and ‘CSL’ denotes a common source line.

While FIG. 3 shows, as an example, the memory block 330 which is formed of NAND flash memory cells, it is to be noted that the memory block 330 of the memory device 300 may be formed of a NOR flash memory, a hybrid flash memory including at least two kinds of memory cells that are combined, or a One-NAND flash memory including a controller built in a memory chip. The operational characteristics of a semiconductor device may be applied to not only a flash memory device in which a charge storing layer is configured by conductive floating gates but also a charge trap flash (CTF) in which a charge storing layer is configured by a dielectric layer.

A voltage supply block 310 of the memory device 300 may provide word line voltages, for example, a program voltage, a read voltage and a pass voltage, to be supplied to respective word lines according to an operation mode and voltages to be supplied to bulks, for example, well regions, where memory cells are formed. The voltage generating operation of the voltage supply block 310 may be performed by the control of a control circuit (not shown). The voltage supply block 310 may generate a plurality of variable read voltages to generate a plurality of read data, select one of the memory blocks (or sectors) of a memory cell array under the control of the control circuit, select one of the word lines of the selected memory block, and provide the word line voltages to the selected word line and unselected word lines.

A read/write circuit 320 of the memory device 300 is controlled by the control circuit, and may operate as a sense amplifier or a write driver according to an operation mode. For example, in a verification/normal read operation, the read/write circuit 320 may operate as a sense amplifier for reading data from the memory cell array. Also, in a program operation, the read/write circuit 320 may operate as a write driver which drives bit lines according to data to be stored in the memory cell array. The read/write circuit 320 may receive data to be written in the memory cell array, from a buffer (not shown), in a program operation, and may drive the bit lines according to the inputted data. To this end, the read/write circuit 320 may include a plurality of page buffers (PB) 322, 324 and 326 respectively corresponding to columns (or bit lines) or pairs of columns (or pairs of bit lines), and a plurality of latches (not shown) may be included in each of the page buffers 322, 324 and 326.

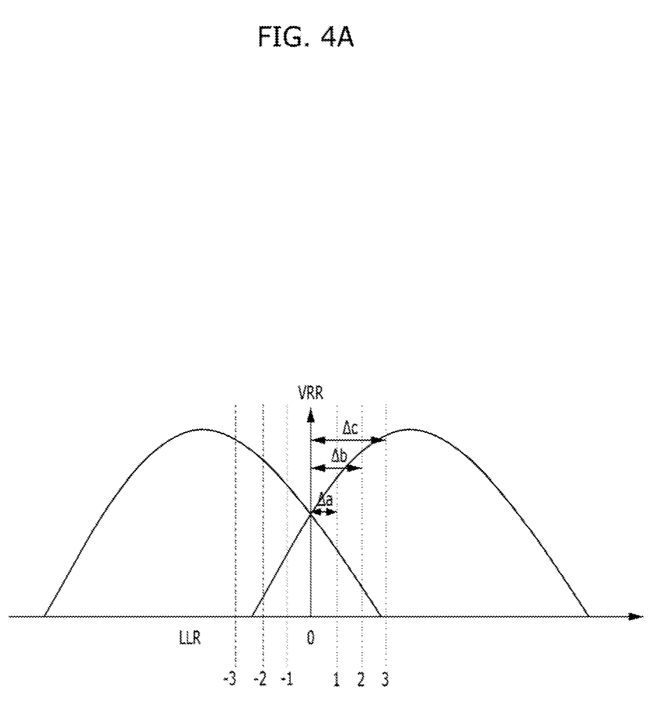

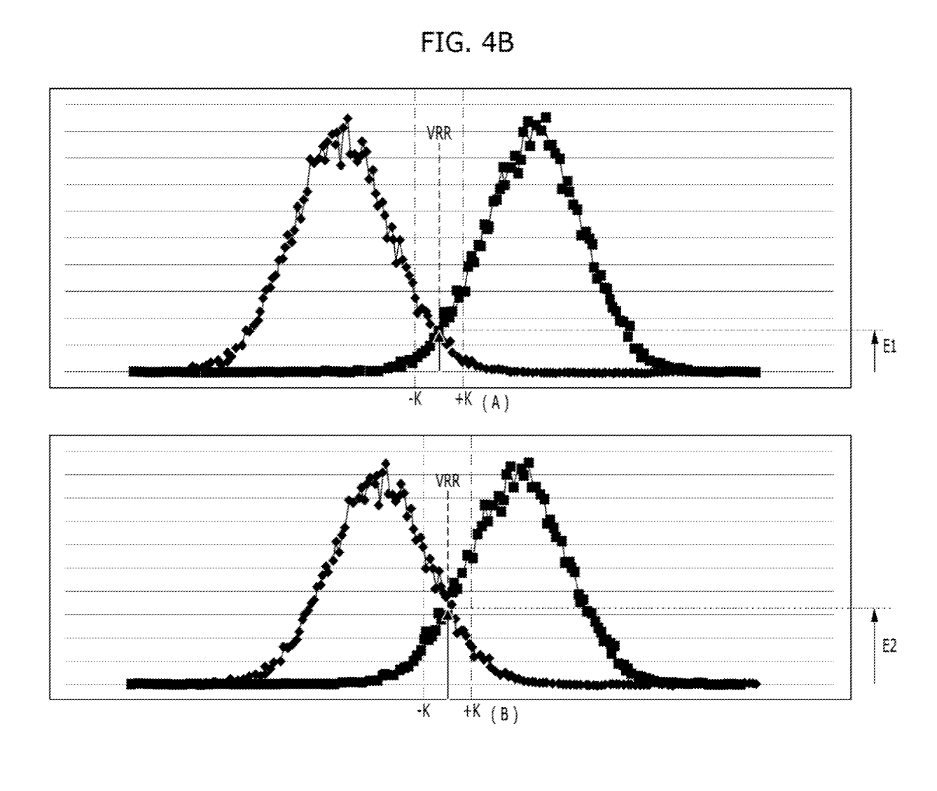

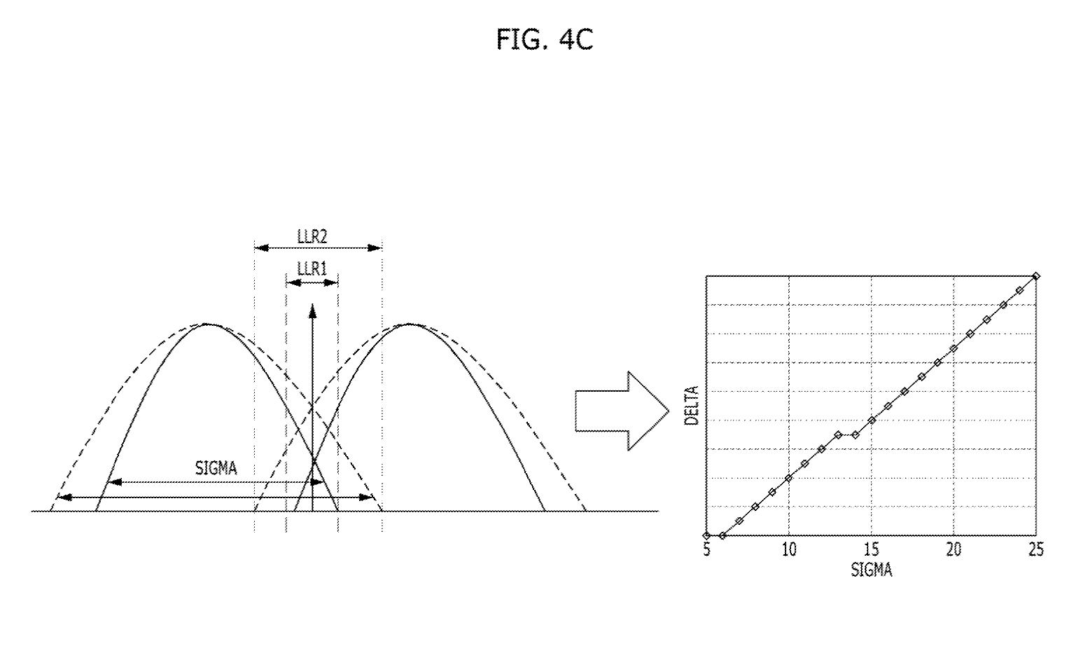

FIGS. 4A to 4C are graphs for describing a low density parity check (LDPC) scheme used for an error correcting function in a nonvolatile memory system.

Referring to FIG. 4A, in an LDPC scheme used for an error correcting function in a nonvolatile memory system, a plurality of memory cells are respectively read using close read levels −1/1, −2/2 and −3/3 that have predetermined intervals Δa, Δb and Δc with a reference read level VRR serving as a center, and a log likelihood ratio (LLR) value is set by referring to variations in the number of data with the value of ‘1’ or the number of data with the value of ‘0’ in the respective read operations.

The LLR value determined in this way exerts a significant influence on the error correction capability of the LDPC scheme. This is because, as shown in FIGS. 4B and 4C, the probabilities of undesired data to be read, that is, error rates E1 and E2, when reading data at a reference read level VRR, may vary significantly according to the threshold voltage level distribution of memory cells.

In detail, referring to FIG. 4B, it may be seen that two graphs (A) and (B) have a significant difference in terms of the number of memory cells with threshold voltage levels that are substantially close to the reference read level VRR, that is, the number of memory cells among the memory cells, of which data values read at the reference read level VRR are unclear as to which values they will have.

First, in the graph (A) where the number of memory cells with threshold voltage levels that are substantially close to the reference read level VRR, is relatively small, the error rate E1 is relatively small. That is to say, when counting the number of memory cells of which threshold voltage levels are within a predetermined level interval between levels VRR+K and VRR−K close to the reference read level VRR, the number is relatively small.

Conversely, in the graph (B) where the number of memory cells with threshold voltage levels that are substantially close to the reference read level VRR is relatively large, the error rate E2 is relatively large. That is to say, when counting the number of memory cells of which threshold voltage levels are within the predetermined level interval between the levels VRR+K and VRR−K close to the reference read level VRR, the number is relatively large.

Referring to FIG. 4C, it may be seen that, for effectively performing an error correcting operation in the LDPC scheme, a read interval DELTA for generating an optimized LLR value should be determined according to a value SIGMA that corresponds to a threshold voltage level distribution of a plurality of memory cells based on a Gaussian model.

Therefore, if a value SIGMA corresponding to a threshold voltage level distribution of a plurality of memory cells is relatively small, that is, if the threshold voltage levels of the memory cells are distributed within a relatively small range, the error correcting operation performed in the LDPC scheme may be sufficient, even when a read interval DELTA for generating an LLR value is relatively small (see the reference symbol LLR1).

Conversely, if a value SIGMA corresponding to a threshold voltage level distribution of a plurality of memory cells is relatively large, that is, if the threshold voltage levels of the memory cells are distributed within a relatively large range, the error correcting operation performed in the LDPC scheme may be sufficient only when a read interval DELTA for generating an LLR value is relatively large (see the reference symbol LLR2).

That is, to efficiently perform an error correcting operation using the LDPC scheme, an operation of determining a read interval DELTA for generating an LLR value with respect to the reference read level VRR is important. That is, a value SIGMA corresponding to a threshold voltage level distribution of a plurality of memory cells may be a factor that determines a read interval DELTA for generating an LLR value. However, in a general nonvolatile memory device, a threshold voltage level distribution of a plurality of memory cells may be changed by applying a stress to the memory cells, for example, repeating read/program cycles, read disturbance between adjacent memory cells during a read operation, retention programs, etc.

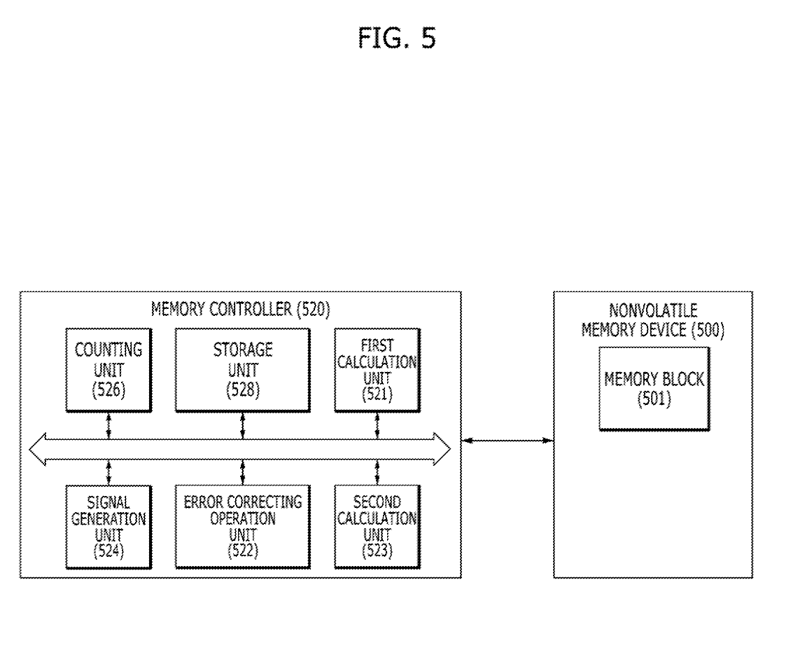

FIG. 5 is a block diagram illustrating a nonvolatile memory system in accordance with an embodiment of the present invention. FIG. 5 shows configurations of a memory controller 520 and a nonvolatile memory device 500 which are based on the configuration of the memory system shown in FIG. 1.

Referring to FIG. 5, the nonvolatile memory system may include the nonvolatile memory device 500 and the memory controller 520. The nonvolatile memory device 500 includes a memory block 501. The memory controller 520 may include an error correcting operation unit 522, a signal generation unit 524, a counting unit 526, a storage unit 528, a first calculation unit 521, and a second calculation unit 523.

The error correcting operation unit 522 finds an LLR value that exerts a significant influence on the performance of an LDPC scheme, through operations of the first calculation unit 521, the second calculation unit 523 and the storage unit 528, when performing an error correcting function by using the LDPC scheme. That is to say, the first calculation unit 521, the second calculation unit 523 and the storage unit 528 may calculate variations of distribution values of the threshold voltage levels of the memory cells included in the memory block 501, by using a linear equation, and may thereby predict the LLR value optimized for the error correcting function of the LDPC scheme. Accordingly, it may be possible to perform the error correcting function quickly and effectively.

The error correcting operation unit 522 may be functionally added to the ECC unit 138 illustrated in FIG. 1. Also, the first calculation unit 521, the second calculation unit 523, the counting unit 526 and the signal generation unit 524 may be functionally added to the processor 134 illustrated in FIG. 1. Further, the storage unit 528 may be functionally added to the memory 144 illustrated in FIG. 1.

For reference, it may be mentioned that the memory block 501 illustrated in FIG. 5 has the same configuration as the memory block 330 shown in FIG. 3 although the inside thereof is not shown in detail. Accordingly, a plurality of memory cells are included in the memory block 501 illustrated in FIG. 5. Therefore, even though the inside of the memory block 501 is not illustrated in detail, it is to be appreciated that a plurality of memory cells are included therein.

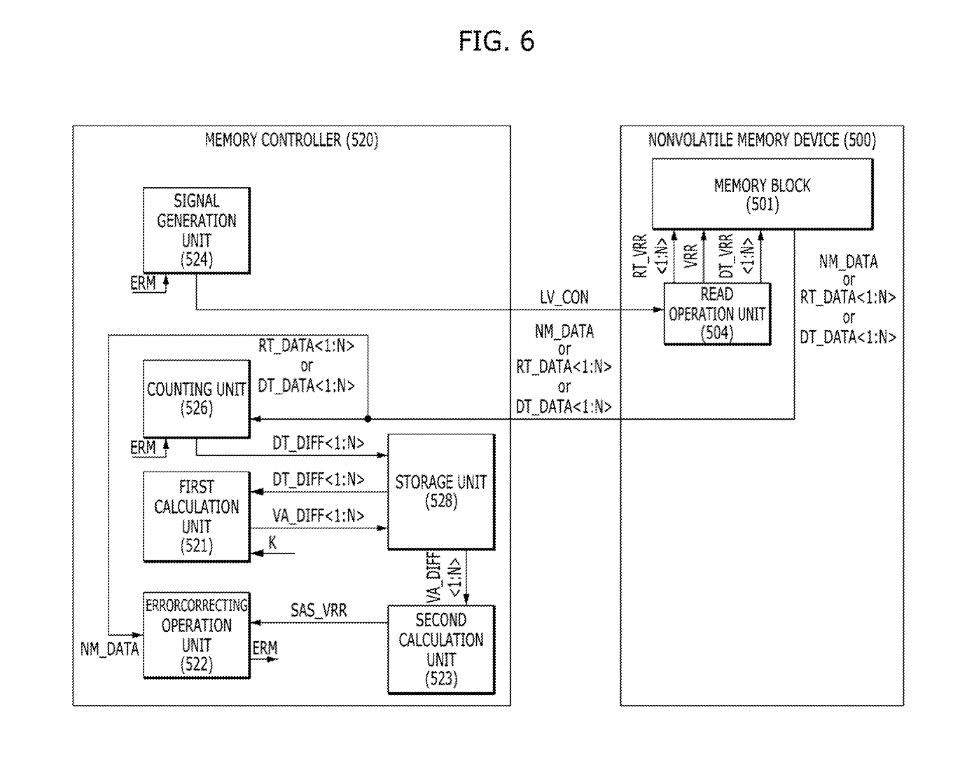

FIG. 6 is a detailed diagram of the nonvolatile memory system shown in FIG. 5.

The nonvolatile memory system may include the nonvolatile memory device 500, and the memory controller 520. The nonvolatile memory device 500 may include the memory block 501 and a read operation unit 504. The memory controller 520 may include the error correcting operation unit 522, the signal generation unit 524, the counting unit 526, the storage unit 528, the first calculation unit 521, and the second calculation unit 523.

The nonvolatile memory device 500 reads the data stored in the memory cells included in the memory block 501, as normal data NM_DATA, by using a reference read level VRR which is supplied through the read operation unit 504.

However, when entering an error correcting operation mode ERM as an error occurred in the normal data NM_DATA may not be recovered only by the operation inside the error correcting operation unit 522, the nonvolatile memory device 500 reads the data stored in the memory cells included in the memory block 501, as N number of distribution data DT_DATA<1:N>, by respectively using N number of distribution read levels DT_VRR<1:N>, and reads the data stored in the memory cells included in the memory block 501, as N number of measurement data RT_DATA<1:N>, by respectively using N number of measurement read levels RT_VRR<1:N>. The N number of distribution read levels DT_VRR<1:N> and the N number of measurement read levels RT_VRR<1:N> are respectively used alternately and sequentially. For example, after the first distribution data DT_DATA<1> is read using the first distribution read level DT_VRR<1>, the first measurement data RT_DATA<1> is read using the first measurement read level RT_VRR<1> in the next order. Then, after the second distribution data DT_DATA<2> is read using the second distribution read level DT_VRR<2>, the second measurement data RT_DATA<2> is read using the second measurement read level RT_VRR<2> in the next order. In this way, the N number of distribution data DT_DATA<1:N> and the N number of measurement data RT_DATA<1:N> are alternately read and transmitted to the memory controller 520.

The read operation unit 504 generates the reference read level VRR, the N number of distribution read levels DT_VRR<1:N> or the N number of measurement read levels RT_VRR<1:N> in response to a level control signal LV_CON which is transferred from the memory controller 520, and reads the data of the memory cells included in the memory block 501, as the normal data NM_DATA, the N number of distribution data DT_DATA<1:N> or the N number of measurement data RT_DATA<1:N>, based thereon. That is to say, the read operation unit 504 generates the reference read level VRR in response to the value of the level control signal LV_CON corresponding to the exit period of the error correcting operation mode ERM, and reads the data of the memory cells included in the memory block 501, as the normal data NM_DATA, based on the generated reference read level VRR. Further, the read operation unit 504 generates the N number of distribution read levels DT_VRR<1:N> or the N number of measurement read levels RT_VRR<1:N> in response to the value of the level control signal LV_CON corresponding to the error correcting operation mode ERM, and reads the data of the memory cells included in the memory block 501, as the N number of distribution data DT_DATA<1:N> or the N number of measurement data RT_DATA<1:N>, based on the generated N number of distribution read levels DT_VRR<1:N> or the generated N number of measurement read levels RT_VRR<1:N>. Which-bit information the level control signal LV_CON includes may be changed according to the magnitude of ‘N’. For example, if ‘N’ is ‘6’, minimum 4-bit information should be included in the level control signal LV_CON such that one reference read level VRR, six distribution read levels DT_VRR<1:6> and sixth measurement read levels RT_VRR<1:6> may be respectively selected.

The memory controller 520 reads the data stored in the memory block 501 of the nonvolatile memory device 500, as the normal data NM_DATA, outside the error correcting operation mode ERM, and checks whether an error occurs in the read normal data NM_DATA.

Even when an error occurs in the normal data NM_DATA, the memory controller 520 does not enter the error correcting operation mode ERM if the error correcting operation unit 522 may correct the error by itself. However, when the error correcting operation unit 522 may not correct the error in the read normal data NM_DATA by itself, the memory controller 520 enters the error correcting operation mode ERM, and recovers the normal data NM_DATA in which the error occurs, based on a recovery read level interval SAS_VRR.

The recovery read level interval SAS_VRR is calculated through the operations of the signal generation unit 524, the counting unit 526, the first calculation unit 521, the second calculation unit 523 and the storage unit 528 in the memory controller 520. In other words, when an error occurs in the normal data NM_DATA read from the memory cells by using the reference read level VRR, before the error correcting operation unit 522 recovers the normal data NM_DATA in which the error occurs, the memory controller 520 performs first an operation of calculating the recovery read level interval SAS_VRR through the signal generation unit 524, the counting unit 526, the first calculation unit 521, the second calculation unit 523 and the storage unit 528.

In detail, the memory controller 520 generates N number of distribution measurement values DT_DIFF<1:N> by measuring the distribution values of the threshold voltage levels of the memory cells at the N number of respective distribution read levels DT_VRR<1:N> which have a preset read level interval dT with the reference read level VRR serving as a center, and determines the recovery read level interval SAS_VRR through calculating the variations of the N number of respective distribution measurement values DT_DIFF<1:N> by using a linear equation. In this way, after the recovery read level interval SAS_VRR is determined, the normal data NM_DATA in which the error occurs is recovered. The memory controller 520 receives the recovery read level interval SAS_VRR, as the read interval of an LLR, performs an LDPC for the normal data NM_DATA in which the error occurs, and recovers the value of the normal data NM_DATA.

To generate the N number of distribution measurement values DT_DIFF<1:N> which represent the distribution values of the threshold voltage levels of the memory cells, by respectively using the N number of distribution read levels DT_VRR<1:N>, not only the N number of distribution read levels DT_VRR<1:N> but also the N number of measurement read levels RT_VRR<1:N>, which are respectively close to the N number of distribution read levels DT_VRR<1:N> with a minimum read level interval, are used by the memory controller 520. Namely, by retaining the N number of distribution read levels DT_VRR<1:N> and the N number of measurement read levels RT_VRR<1:N> when they are close to each other with the minimum read level interval, the data stored in the memory cells are read by respectively using any one distribution read level and a measurement read level corresponding to it, and the difference between the values of two read data becomes any one distribution measurement value that may be measured by using any one distribution read level and represents the distribution value of the threshold voltage levels of the memory cells. For example, after reading the data stored in the memory cells, as the first distribution data DT_DATA<1> and the first measurement data RT_DATA<1>, by respectively using the first distribution read level DT_VRR<1> and the first measurement read level RT_VRR<1> close thereto with the minimum read level interval, by counting the difference between the values of the first distribution data DT_DATA<1> and the first measurement data RT_DATA<1>, the first distribution measurement value DT_DIFF<1> that may be measured by using the first distribution read level DT_VRR<1> and represents the distribution value of the threshold voltage levels of the memory cells is acquired. That is to say, when assuming that the number of ‘1’ in the value of the first distribution data DT_DATA<1> is ‘K’ and the number of ‘1’ in the value of the first measurement data RT_DATA<1> is ‘L’, the difference ‘K−L’ becomes the first distribution measurement value DT_DIFF<1>. In the same manner, after reading the data stored in the memory cells, as the third distribution data DT_DATA<3> and the third measurement data RT_DATA<3>, by respectively using the third distribution read level DT_VRR<3> and the third measurement read level RT_VRR<3> close thereto with the minimum read level interval, by counting the difference between the values of the third distribution data DT_DATA<3> and the third measurement data RT_DATA<3>, the third distribution measurement value DT_DIFF<3> that may be measured by using the third distribution read level DT_VRR<3> and represents the distribution value of the threshold voltage levels of the memory cells is acquired. That is to say, when assuming that the number of ‘1’ in the value of the third distribution data DT_DATA<3> is ‘S’ and the number of ‘1’ in the value of the third measurement data RT_DATA<3> is ‘D’, the difference ‘S−D’ becomes the third distribution measurement value DT_DIFF<3>.

For reference, the minimum read level interval that represents the closed state of the N number of distribution read levels DT_VRR<1:N> and the N number of measurement read levels RT_VRR<1:N> is not an absolute value. In other words, which degree of a read level interval the minimum read level interval will have may be controlled in a variety of ways according to the characteristics of the nonvolatile memory device 500. Namely, the minimum read level interval means a smallest read level interval that is controllable to generally read the data stored in a plurality of memory cells, and the value thereof may be changed according to how the read operation unit 504 of the nonvolatile memory device 500 may read the data stored in the memory cells with which precise degree of a read level interval difference. Therefore, the fact that the N number of distribution read levels DT_VRR<1:N> and the N number of measurement read levels RT_VRR<1:N> will have a close degree of a read level interval difference may be controlled in a variety of ways by a designer.

The preset read level interval dT, which the N number of distribution read levels DT_VRR<1:N> should have to determine the recovery read level interval SAS_VRR in the memory controller 520, is a read level interval that corresponds to K times the minimum read level interval controllable to read the data stored in the memory cells. For example, when assuming that the minimum read level interval controllable to read the data stored in the memory cells is ‘0.1V’ and ‘K’ is ‘8’, the preset read level interval dT becomes ‘0.8V’, and the N number of distribution read levels DT_VRR<1:N> are set to a state in which they have the preset read level interval dT of ‘0.8V’.

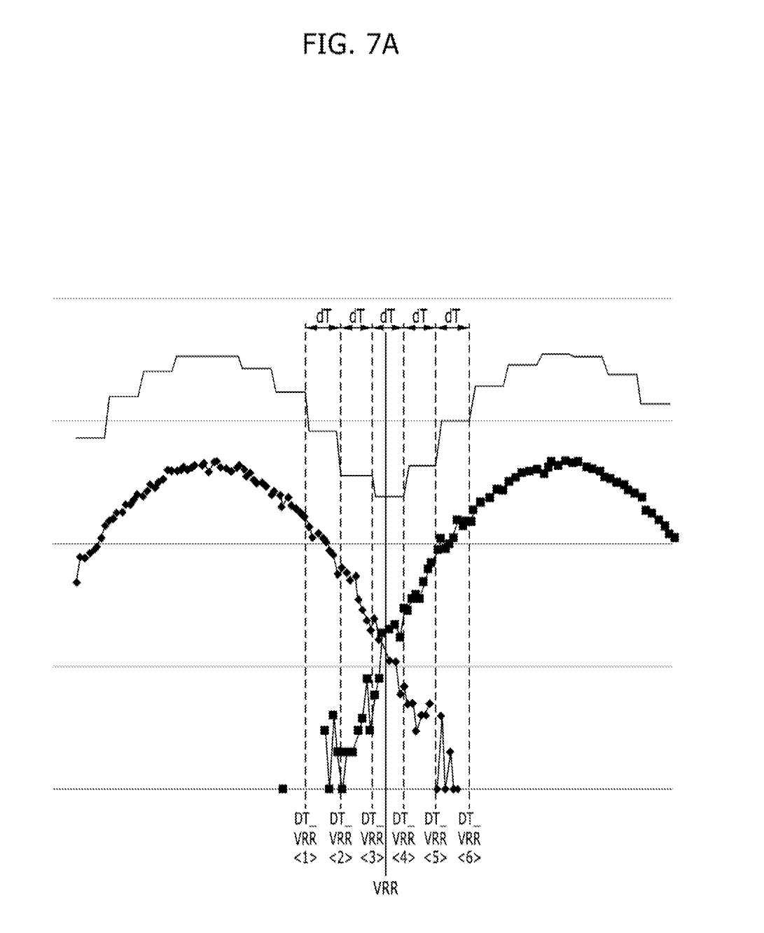

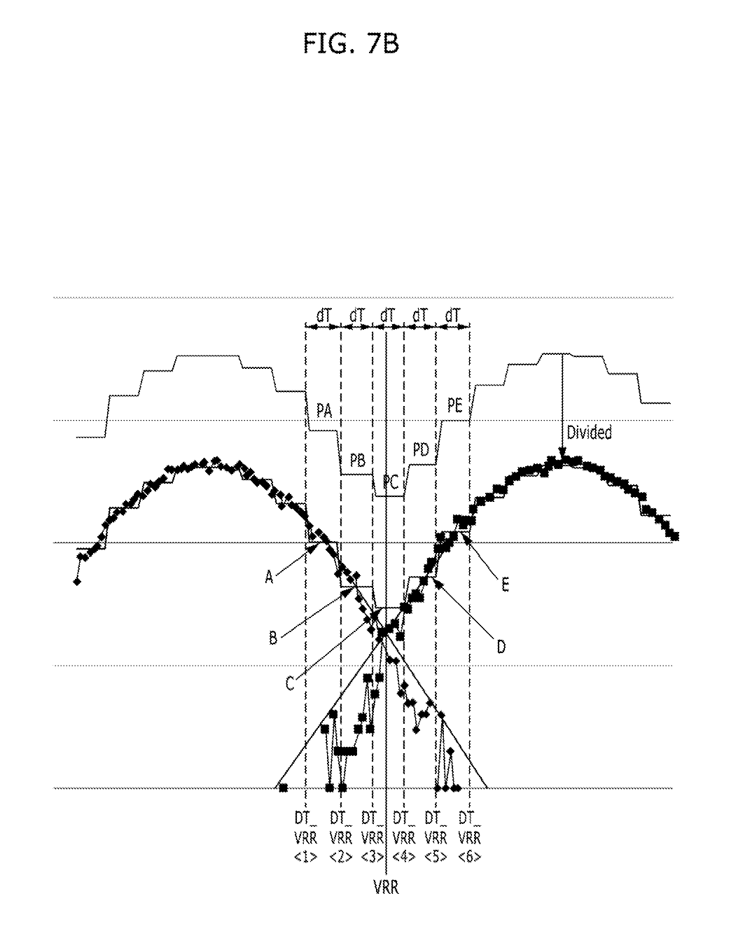

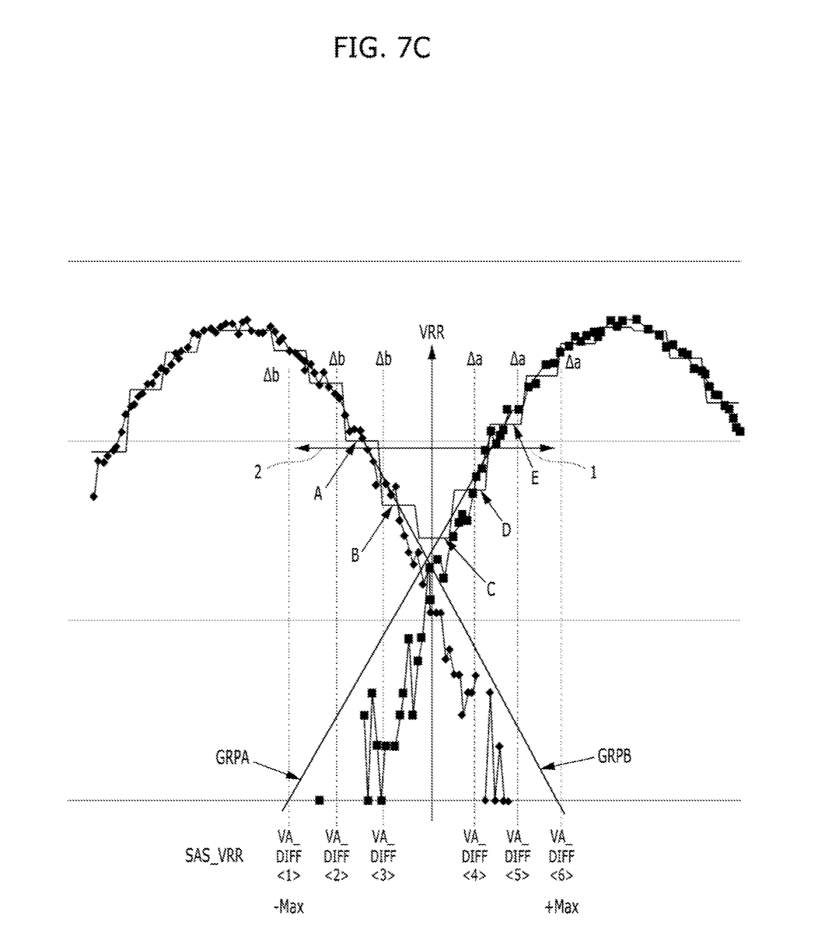

The reason why the preset read level interval dT should have the read level interval that corresponds to K times the minimum read level interval is because the change in slope of the distribution value of the threshold voltage levels of the memory cells should be sufficiently reflected on the N number of distribution measurement values DT_DIFF<1:N>. That is to say, when a pattern, in which the distribution value of the threshold voltage levels of the memory cells is changed, is included at least partially between the start distribution read level DT_VRR<1> and the last distribution read level DT_VRR<N> of the N number of distribution read levels DT_VRR<1:N>, it may be possible to calculate the effective recovery read level interval SAS_VRR by using the N number of distribution read levels DT_VRR<1:N>. For example, when ‘N’ is ‘6’ as shown in FIG. 7A, it may be seen that setting is made such that six distribution measurement values DT_DIFF<1:N> are determined when the preset read level interval dT of such a magnitude to include all portions where the distribution value of the threshold voltage levels of the memory cells is largely changed with the reference read level VRR serving as a center, is retained.

Each of the values of ‘N’ and ‘K’ is a value that may be controlled in a variety of ways by a designer among natural numbers equal to or greater than 2. When the values of ‘N’ and ‘K’ are respectively controlled appropriately, it may be possible to quickly calculate the effective recovery read level interval SAS_VRR. In other words, if the value of ‘N’ is too large and the value of ‘K’ is correspondingly too small when the read level interval between the start distribution read level DT_VRR<1> and the last distribution read level DT_VRR<N> of the N number of distribution read levels DT_VRR<1:N> is determined, while the pattern in which the distribution value of the threshold voltage levels of the memory cells is changed is sufficiently reflected on the N number of distribution measurement values DT_DIFF<1:N> and thus it may be possible to determine the precise recovery read level interval SAS_VRR, the number of operations to be performed in the memory controller 520 to determine the recovery read level interval SAS_VRR may become too large. Conversely, if the value of ‘N’ is too small and the value of ‘K’ is correspondingly too large, while the number of operations to be performed in the memory controller 520 to determine the recovery read level interval SAS_VRR may be remarkably decreased, the recovery read level interval SAS_VRR may be determined with poor precision since the probability of the pattern in which the distribution value of the threshold voltage levels of the memory cells is changed, not to be sufficiently reflected on the N number of distribution measurement values DT_DIFF<1:N>, increases.

The process of determining the recovery read level interval SAS_VRR by calculating the variations of the N number of distribution measurement values DT_DIFF<1:N> by using a linear equation in the memory controller 520 will be described below with reference to FIGS. 7B and 7C.

First, by dividing the values of the N number of respective distribution measurement values DT_DIFF<1:N> by the minimum read level interval of K times for comparting the preset read level interval dT, N number of distribution variation values VA_DIFF<1:N> are generated. Thereafter, by extending the variations of the respective N number of distribution variation values VA_DIFF<1:N> by using a linear equation, the interval between read levels corresponding to level value intercepts in both directions from the reference read level VRR is determined as the recovery read level interval SAS_VRR.

The reason why the N number of distribution variation values VA_DIFF<1:N> are generated is because the N number of distribution variation values VA_DIFF<1:N> rather than the N number of distribution measurement values DT_DIFF<1:N> may precisely reflect the pattern in which the distribution value of the threshold voltage levels of the memory cells is changed. Namely, as described above, although the pattern in which the distribution value of the threshold voltage levels of the memory cells is changed may be precisely reflected as the preset read level interval dT is decreased, the number of operations to be performed in the memory controller 520 is increased too much when the preset read level interval dT is decreased to be too small. Thus, in the embodiment of the present invention, a method is used, where, after generating the N number of distribution measurement values DT_DIFF<1:N> by using the preset read level interval dT with a sufficiently large value, a variation in the distribution value of the threshold voltage levels of the memory cells that occurs averagely in each minimum read level interval between the N number of distribution variation values VA_DIFF<1:N> is measured through an operation of dividing the N number of distribution measurement values DT_DIFF<1:N> by ‘K’ corresponding to the minimum read level interval.

For example, referring to FIG. 7B where ‘N’ is ‘6’ was described as an example, it may be seen that ‘PA, PB, PC, PD and PE’ as six distribution measurement values DT_DIFF<1:6> have a variation value RR higher than an actual variation value R in the threshold voltage levels of the memory cells, since counting is performed when all the memory cells with the threshold voltage levels included between the six distribution measurement values DT_DIFF<1:6> are accumulated. However, it may be seen that the variation value RR of ‘A, B, C, D and E’ as six distribution variation values VA_DIFF<1:6> generated by performing a calculation of dividing ‘PA, PB, PC, PD and PE’ as the six distribution measurement values DT_DIFF<1:6> by ‘K’ is determined when the variation value RR is approximately the actual variation value R in the threshold voltage levels of the memory cells.

Referring to FIG. 7C which is shown by enlarging the six distribution variation values VA_DIFF<1:6> of FIG. 7B, it may be seen that ‘C, D and E’ as the three distribution variation values VA_DIFF<4:6> corresponding to one direction 1 from the reference read level VRR, among ‘A, B, C, D and E’ as the six distribution variation values VA_DIFF<1:6>, are changed in their values by ‘ΔA’. Accordingly, a linear graph GRPA, which extends passing through the reference read level VRR in the one direction 1, may be drawn by assuming that the distribution value slope of the memory cells will continuously retain ‘ΔA’. Also, it may be seen that ‘C, B and A’ as the three distribution variation values VA_DIFF<3:1> corresponding to the other direction 2 from the reference read level VRR, among ‘A, B, C, D and E’ as the six distribution variation values VA_DIFF<1:6>, are changed in their values by ‘ΔB’. Accordingly, a linear graph GRPB, which extends passing through the reference read level VRR in the other direction 2, may be drawn by assuming that the distribution value slope of the memory cells will continuously retain ‘ΔB’. By determining the Interval between read levels +MAX and −MAX corresponding to the level value intercepts of the linear graphs GRPA and GRPB drawn in this way, as the recovery read level interval SAS_VRR, it may be seen that a variation in the distribution value of the threshold voltage levels of the memory cells is reflected on the recovery read level interval SAS_VRR.

The signal generation unit 524 generates the level control signal LV_CON with a value for controlling the normal data NM_DATA to be read from the read operation unit 504, outside the error correcting operation mode ERM, and generates the level control signal LV_CON with a value for controlling the N number of distribution data DT_DATA<1:N> or the N number of measurement data RT_DATA<1:N> to be read from the read operation unit 504, during the error correcting operation mode ERM. In other words, the signal generation unit 524 serves to control the value of the level control signal LV_CON and determine which read voltage is to be used when reading data from the memory block 501. The level control signal LV_CON may be a signal which includes plural-bit information according to the magnitude of ‘N’.

The counting unit 526 counts the differences of the N number of distribution data DT_DATA<1:N> and the N number of measurement data RT_DATA<1:N> during the error correcting operation mode ERM, and generates the N number of distribution measurement values DT_DIFF<1: N>.

The storage unit 528 stores the N number of distribution measurement values DT_DIFF<1:N> and the N number of distribution variation values VA_DIFF<1:N>. That is to say, the storage unit 528 stores N number of distribution measurement values DT_DIFF<1:N> and the N number of distribution variation values VA_DIFF<1:N> which should retain their values during the operation of the counting unit 526, the operation of the first calculation unit 521 and the operation of the second calculation unit 523.

The storage unit 528 may be configured in the form that includes N number of first storages (not shown) for respectively storing the N number of distribution measurement values DT_DIFF<1:N> and N number of second storages (not shown) for respectively storing the N number of distribution variation values VA_DIFF<1:N>. In this case, the operation of the first calculation unit 521 may be performed in parallel. In other words, after reading the N number of distribution measurement values DT_DIFF<1:N> at once in parallel and performing all calculations in parallel, the N number of distribution variation values VA_DIFF<1:N> generated may be stored at once in parallel.

Since the first calculation unit 521 operates after the counting unit 526 operates and then the second calculation unit 523 operates, the storage unit 528 may be configured in the form that includes N number of storages (not shown) for respectively storing the N number of distribution measurement values DT_DIFF<1:N> in response to an operation result of the counting unit 526 and for respectively storing the N number of distribution variation values VA_DIFF<1:N> in response to an operation result of the first calculation unit 521. In this case, the operation of the first calculation unit 521 may not be performed in parallel. Namely, after performing calculations by sequentially reading the N number of distribution measurement values DT_DIFF<1:N> one by one, the N number of distribution variation values VA_DIFF<1:N> resultantly generated one by one should be sequentially stored one by one.

The first calculation unit 521 reads the respective N number of distribution measurement values DT_DIFF<1:N> stored in the storage unit 528, performs calculations of dividing the N number of distribution measurement values DT_DIFF<1:N> by the minimum read level interval of K times for comparting the preset read level interval dT, and stores the N number of distribution variation values VA_DIFF<1:N> generated by the calculations, in the storage unit 528.

The second calculation unit 523 reads the respective N number of distribution variation values VA_DIFF<1:N> stored in the storage unit 528, calculates the variations of the values, generates a linear equation, finds read levels corresponding to level value intercepts in both directions from the reference read level VRR by using the linear equation generated by the calculations, and determines the interval between the two found read levels, as the recovery read level interval SAS_VRR.

The error correcting operation unit 522 detects whether an error occurs in the normal data NM_DATA and determines whether to enter the error correcting operation mode ERM, outside the error correcting operation mode ERM. In detail, the error correcting operation unit 522 performs an operation of detecting whether an error occurs in the normal data NM_DATA read from the nonvolatile memory device 500 outside the error correcting operation mode ERM. When an error occurs, the error correcting operation unit 522 enters the error correcting operation mode ERM, and when an error has not occurred, the error correcting operation unit 522 continuously retains the state exited from the error correcting operation mode ERM. A reference for determining that an error occurs in the normal data NM_DATA corresponds to the case where an error incapable of being immediately corrected in the error correcting operation unit 522 occurs. For example, when assuming that the normal data NM_DATA is 16-bit data, since an error up to 2 bits among the 16-bit data may be immediately corrected by the error correcting operation unit 522 through a simple operation such as a parity checking scheme, it is not determined that an error occurs. Nevertheless, since it may be impossible to immediately correct an error exceeding 3 bits, it is determined that an error occurs. Additionally, the reference by which the error correcting operation unit 522 determines the occurrence of an error may be changed in a variety of ways.

The error correcting operation unit 522 recovers the normal data NM_DATA in which an error occurs, based on the recovery read level interval SAS_VRR determined by the second calculation unit 523, during the error correcting operation mode ERM. That is to say, the error correcting operation unit 522 receives the recovery read level interval SAS_VRR determined by the second calculation unit 523, as the read interval of an LLR, during the error correcting operation mode ERM, performs an LDPC for the normal data NM_DATA in which an error occurs, and recovers the value of the normal data NM_DATA. Therefore, the error correcting operation unit 522 may perform the LDPC and recover the normal data NM_DATA, when information with threshold voltage level distribution of the memory cells included in the nonvolatile memory device 500 is reflected on the read interval of the LLR.

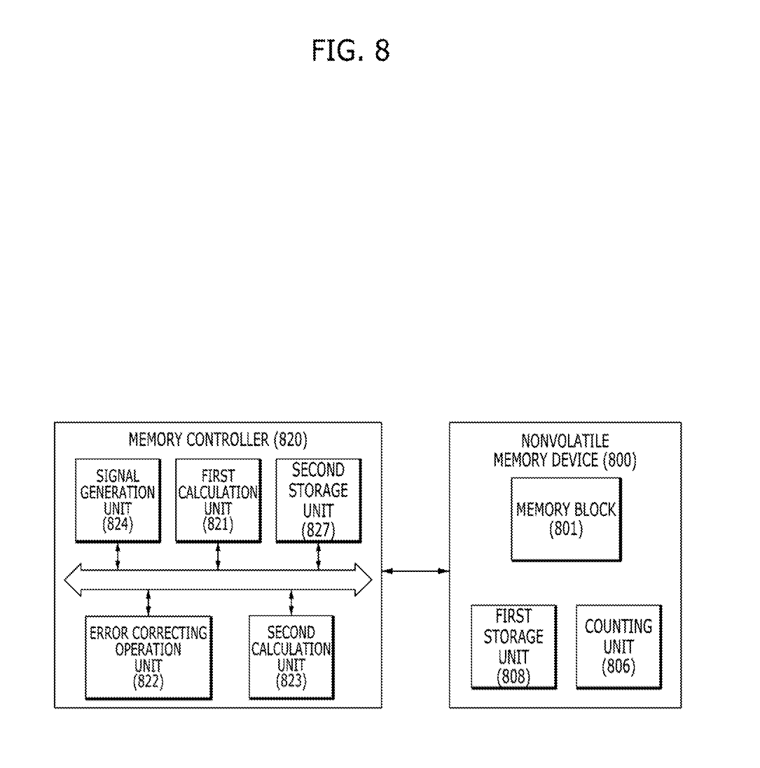

FIG. 8 is a block diagram illustrating a nonvolatile memory system in accordance with an embodiment of the present invention. FIG. 8 shows configurations of a memory controller 820 and a nonvolatile memory device 800 based on the configuration of the memory system shown in FIG. 1.

Referring to FIG. 8, the nonvolatile memory system may include the nonvolatile memory device 800 and the memory controller 820. The nonvolatile memory device 800 may include a memory block 801, a first storage unit 808, and a counting unit 806. The memory controller 820 may include an error correcting operation unit 822, a signal generation unit 824, a second storage unit 827, a first calculation unit 821, and a second calculation unit 823.

The error correcting operation unit 822 included in the memory controller 820 finds an LLR value that exerts a significant influence on the performance of an LDPC scheme, through operations of the first calculation unit 821, the second calculation unit 823 and the second storage unit 827, when performing an error correcting function by using the LDPC scheme. That is to say, the first calculation unit 821, the second calculation unit 823 and the storage unit 827 may calculate variations of distribution values of the threshold voltage levels of the memory cells included in the memory block 801, by using a linear equation, and may thereby predict the LLR value optimized for the error correcting function of the LDPC scheme. Accordingly, the error correcting function may be performed quickly and effectively.

The error correcting operation unit 822 may be functionally added to the ECC unit 138 illustrated in FIG. 1. Also, the first calculation unit 821, the second calculation unit 823 and the signal generation unit 824 may be functionally added to the processor 134 illustrated in FIG. 1. Further, the second storage unit 827 may be functionally added to the memory 144 illustrated in FIG. 1. Moreover, the counting unit 806 and the first storage unit 808 included in the nonvolatile memory device 800 are component elements which are not illustrated in FIG. 1 and should be added to the nonvolatile memory device 800 for an embodiment of the invention.

For reference, it may be mentioned that the memory block 801 illustrated in FIG. 8 has the same configuration as the memory block 330 shown in FIG. 3 although the inside thereof is not shown in detail. Accordingly, a plurality of memory cells are included in the memory block 801 illustrated in FIG. 8. Therefore, even though the inside of the memory block 801 is not illustrated in detail in the drawing which is described below and shows the nonvolatile memory device 800 in accordance with an embodiment of the invention, it is to be appreciated that a plurality of memory cells are included therein.

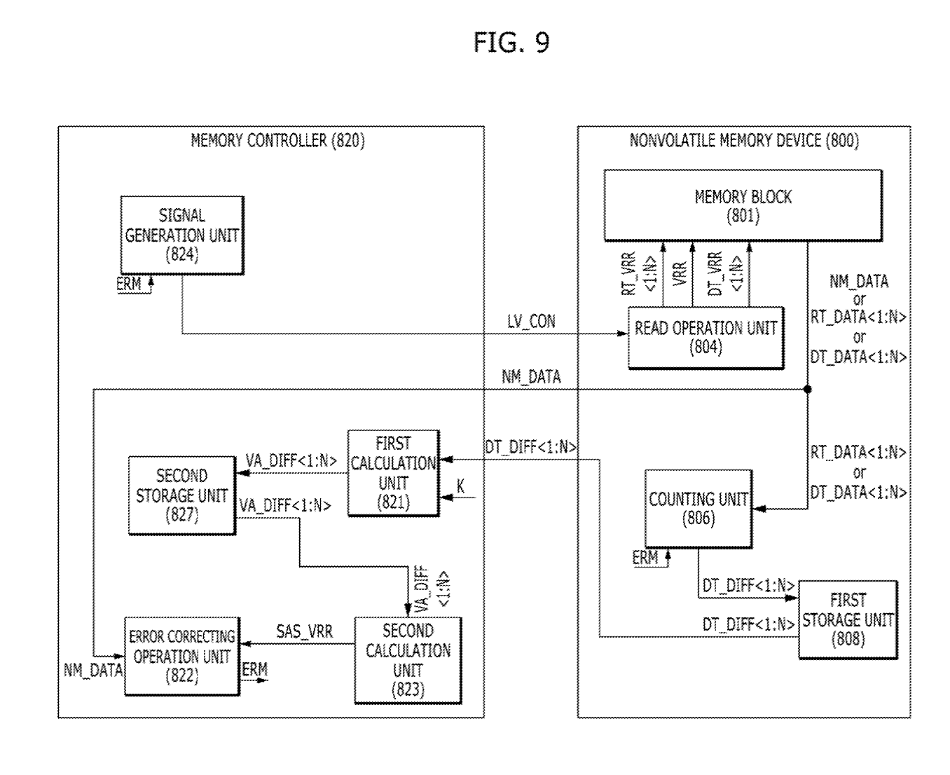

FIG. 9 is a detailed diagram of the nonvolatile memory system shown in FIG. 8.

The nonvolatile memory system may include the nonvolatile memory device 800 and the memory controller 820. The nonvolatile memory device 800 may include the memory block 801, a read operation unit 804, the counting unit 806, and the first storage unit 808. The memory controller 820 may include the error correcting operation unit 822, the signal generation unit 824, the second storage unit 827, the first calculation unit 821, and the second calculation unit 823.

The nonvolatile memory device 800 reads the data stored in the memory cells included in the memory block 801, as normal data NM_DATA, by using a reference read level VRR which is supplied through the read operation unit 804.

However, when entering an error correcting operation mode ERM as an error occurred in the normal data NM_DATA may not be recovered only by the operation inside the error correcting operation unit 822, the nonvolatile memory device 800 reads the data stored in the memory cells included in the memory block 801, as N number of distribution data DT_DATA<1:N>, by respectively using N number of distribution read levels DT_VRR<1:N>, and reads the data stored in the memory cells included in the memory block 801, as N number of measurement data RT_DATA<1:N>, by respectively using N number of measurement read levels RT_VRR<1:N>. The N number of distribution read levels DT_VRR<1:N> and the N number of measurement read levels RT_VRR<1:N> are respectively used alternately and sequentially. For example, after the first distribution data DT_DATA<1> is read using the first distribution read level DT_VRR<1>, the first measurement data RT_DATA<1> is read using the first measurement read level RT_VRR<1> in the next order. Then, after the second distribution data DT_DATA<2> is read using the second distribution read level DT_VRR<2>, the second measurement data RT_DATA<2> is read using the second measurement read level RT_VRR<2> in the next order. In this way, the N number of distribution data DT_DATA<1:N> and the N number of measurement data RT_DATA<1:N> are alternately read.

In order for the nonvolatile memory device 800 to generate N number of distribution measurement values DT_DIFF<1:N> which represent the distribution values of the threshold voltage levels of the memory cells, by respectively using the N number of distribution read levels DT_VRR<1:N>, not only the N number of distribution read levels DT_VRR<1:N> but also the N number of measurement read levels RT_VRR<1:N>, which are respectively close to the N number of distribution read levels DT_VRR<1:N> with a minimum read level interval, are used. Namely, by retaining the N number of distribution read levels DT_VRR<1:N> and the N number of measurement read levels RT_VRR<1:N> when they are close to each other with the minimum read level interval, the data stored in the memory cells are read by respectively using any one distribution read level and a measurement read level corresponding to it, and the difference between the values of two read data becomes any one distribution measurement value that may be measured by using any one distribution read level and represents the distribution value of the threshold voltage levels of the memory cells. For example, after reading the data stored in the memory cells, as the first distribution data DT_DATA<1> and the first measurement data RT_DATA<1>, by respectively using the first distribution read level DT_VRR<1> and the first measurement read level RT_VRR<1> close thereto with the minimum read level interval, by counting the difference between the values of the first distribution data DT_DATA<1> and the first measurement data RT_DATA<1>, the first distribution measurement value DT_DIFF<1> that may be measured by using the first distribution read level DT_VRR<1> and represents the distribution value of the threshold voltage levels of the memory cells is acquired. That is to say, when assuming that the number of ‘1’ in the value of the first distribution data DT_DATA<1> is ‘K’ and the number of ‘1’ in the value of the first measurement data RT_DATA<1> is ‘L’, the difference ‘K−L’ becomes the first distribution measurement value DT_DIFF<1>. In the same manner, after reading the data stored in the memory cells, as the third distribution data DT_DATA<3> and the third measurement data RT_DATA<3>, by respectively using the third distribution read level DT_VRR<3> and the third measurement read level RT_VRR<3> close thereto with the minimum read level interval, by counting the difference between the values of the third distribution data DT_DATA<3> and the third measurement data RT_DATA<3>, the third distribution measurement value DT_DIFF<3> that may be measured by using the third distribution read level DT_VRR<3> and represents the distribution value of the threshold voltage levels of the memory cells is acquired. That is to say, when assuming that the number of ‘1’ in the value of the third distribution data DT_DATA<3> is ‘S’ and the number of ‘1’ in the value of the third measurement data RT_DATA<3> is ‘D’, the difference ‘S−D’ becomes the third distribution measurement value DT_DIFF<3>.

For reference, the minimum read level interval that represents the closed state of the N number of distribution read levels DT_VRR<1:N> and the N number of measurement read levels RT_VRR<1:N> is not an absolute value. In other words, which degree of a read level interval the minimum read level interval will have may be controlled in a variety of ways according to the characteristics of the nonvolatile memory device 800. Namely, the minimum read level interval means a smallest read level interval that is controllable to generally read the data stored in a plurality of memory cells, and the value thereof may be changed according to that the read operation unit 804 of the nonvolatile memory device 800 may read the data stored in the memory cells with which precise degree of a read level interval difference. Therefore, the fact that the N number of distribution read levels DT_VRR<1:N> and the N number of measurement read levels RT_VRR<1:N> will have which close degree of a read level interval difference may be controlled in a variety of ways by a designer.

The read operation unit 804 generates the reference read level VRR, the N number of distribution read levels DT_VRR<1:N> or the N number of measurement read levels RT_VRR<1:N> in response to a level control signal LV_CON which is transferred from the memory controller 820, and reads the data of the memory cells included in the memory block 801, as the normal data NM_DATA, the N number of distribution data DT_DATA<1:N> or the N number of measurement data RT_DATA<1:N>, based thereon. That is to say, the read operation unit 804 generates the reference read level VRR in response to the value of the level control signal LV_CON corresponding to the exit period of the error correcting operation mode ERM, and reads the data of the memory cells included in the memory block 801, as the normal data NM_DATA, based on the generated reference read level VRR. Further, the read operation unit 804 generates the N number of distribution read levels DT_VRR<1:N> or the N number of measurement read levels RT_VRR<1:N> in response to the value of the level control signal LV_CON corresponding to the error correcting operation mode ERM, and reads the data of the memory cells included in the memory block 801, as the N number of distribution data DT_DATA<1:N> or the N number of measurement data RT_DATA<1:N>, based on the generated N number of distribution read levels DT_VRR<1:N> or the generated N number of measurement read levels RT_VRR<1:N>. Which-bit information the level control signal LV_CON includes may be changed according to the magnitude of ‘N’. For example, if ‘N’ is ‘6’, minimum 4-bit information should be included in the level control signal LV_CON such that one reference read level VRR, six distribution read levels DT_VRR<1:6> and sixth measurement read levels RT_VRR<1:6> may be respectively selected.

The counting unit 806 counts the differences of the N number of distribution data DT_DATA<1:N> and the N number of measurement data RT_DATA<1:N> during the error correcting operation mode ERM, and generates the N number of distribution measurement values DT_DIFF<1:N>.

The first storage unit 808 stores the N number of distribution measurement values DT_DIFF<1:N>. That is to say, the first storage unit 808 stores the N number of distribution measurement values DT_DIFF<1:N> which are generated as the operation result of the counting unit 806.

The memory controller 820 reads the data stored in the memory block 801 of the nonvolatile memory device 800, as the normal data NM_DATA, outside the error correcting operation mode ERM, and checks whether an error occurs in the read normal data NM_DATA.

Even when an error occurs in the normal data NM_DATA, the memory controller 820 does not enter the error correcting operation mode ERM if the error correcting operation unit 822 may correct the error by itself. However, when the error correcting operation unit 822 may not correct the error occurred in the read normal data NM_DATA by itself, the memory controller 820 enters the error correcting operation mode ERM, and recovers the normal data NM_DATA in which the error occurs, based on a recovery read level interval SAS_VRR.

The recovery read level interval SAS_VRR is calculated through the operations of the signal generation unit 824, the first calculation unit 821, the second calculation unit 823 and the second storage unit 827 in the memory controller 820. In other words, when an error occurs in the normal data NM_DATA read from the memory cells by using the reference read level VRR, before the error correcting operation unit 822 recovers the normal data NM_DATA in which the error occurs, the memory controller 820 performs first an operation of calculating the recovery read level interval SAS_VRR through the signal generation unit 824, the first calculation unit 821, the second calculation unit 823 and the second storage unit 827.

In detail, the memory controller 820 controls N number of distribution measurement values DT_DIFF<1:N> to be generated in the nonvolatile memory device 800 by measuring the distribution values of the threshold voltage levels of the memory cells at the N number of respective distribution read levels DT_VRR<1:N> which have a preset read level interval dT with the reference read level VRR serving as a center, and determines the recovery read level interval SAS_VRR through calculating the variations of the N number of respective distribution measurement values DT_DIFF<1:N> by using a linear equation. In this way, after the recovery read level interval SAS_VRR is determined, the normal data NM_DATA in which the error occurs is recovered. The memory controller 820 receives the recovery read level interval SAS_VRR, as the read interval of an LLR, performs an LDPC for the normal data NM_DATA in which the error occurs, and recovers the value of the normal data NM_DATA.

The preset read level interval dT, which the N number of distribution read levels DT_VRR<1:N> should retain to determine the recovery read level interval SAS_VRR in the memory controller 820, is a read level interval that corresponds to K times the minimum read level interval controllable to read the data stored in the memory cells. For example, when assuming that the minimum read level interval controllable to read the data stored in the memory cells is ‘0.1V’ and ‘K’ is ‘8’, the preset read level interval dT becomes ‘0.8V’, and the N number of distribution read levels DT_VRR<1:N> are set to a state in which they have the preset read level interval dT of ‘0.8V’.

The reason the preset read level interval dT should have the read level interval that corresponds to K times the minimum read level interval is because the change in slope of the distribution value of the threshold voltage levels of the memory cells should be sufficiently reflected on the N number of distribution measurement values DT_DIFF<1:N>. That is to say, when a pattern in which the distribution value of the threshold voltage levels of the memory cells is changed is included at least partially between the start distribution read level DT_VRR<1> and the last distribution read level DT_VRR<N> of the N number of distribution read levels DT_VRR<1:N>, it may be possible to calculate the effective recovery read level interval SAS_VRR by using the N number of distribution read levels DT_VRR<1:N>. For example, when ‘N’ is ‘6’ as shown in FIG. 7A, it may be seen that setting is made such that six distribution measurement values DT_DIFF<1:N> are determined when the preset read level interval dT of such a magnitude enough to include all portions where the distribution value of the threshold voltage levels of the memory cells is largely changed with the reference read level VRR serving as a center, is retained.

Each of the values of ‘N’ and ‘K’ is a value that may be controlled in a variety of ways by a designer and may be among natural numbers equal to or greater than 2. When the values of ‘N’ and ‘K’ are controlled appropriately, it may be possible to quickly calculate the effective recovery read level interval SAS_VRR. In other words, if the value of ‘N’ is too large and the value of ‘K’ is correspondingly too small when the read level interval between the start distribution read level DT_VRR<1> and the last distribution read level DT_VRR<N> of the N number of distribution read levels DT_VRR<1:N> is determined, while the pattern in which the distribution value of the threshold voltage levels of the memory cells is changed, is sufficiently reflected on the N number of distribution measurement values DT_DIFF<1:N> and thus it may be possible to determine the precise recovery read level interval SAS_VRR, the number of operations to be performed in the memory controller 820 to determine the recovery read level interval SAS_VRR may become too large. Conversely, if the value of ‘N’ is too small and the value of ‘K’ is correspondingly too large, while the number of operations to be performed in the memory controller 820 to determine the recovery read level interval SAS_VRR may be remarkably decreased, the recovery read level interval SAS_VRR may be determined with poor precision since the probability of the pattern in which the distribution value of the threshold voltage levels of the memory cells is changed, not to be sufficiently reflected on the N number of distribution measurement values DT_DIFF<1:N>, increases.

The process of determining the recovery read level interval SAS_VRR by calculating the variations of the N number of distribution measurement values DT_DIFF<1:N> by using a linear equation in the memory controller 820 will be described below with reference to FIGS. 7B and 7C.

First, by dividing the values of the N number of respective distribution measurement values DT_DIFF<1:N> by the minimum read level interval of K times for comparting the preset read level interval dT, N number of distribution variation values VA_DIFF<1:N> are generated. Thereafter, by extending the variations of the respective N number of distribution variation values VA_DIFF<1:N> by using a linear equation, the interval between read levels corresponding to level value intercepts in both directions from the reference read level VRR is determined as the recovery read level interval SAS_VRR.

The reason why the N number of distribution variation values VA_DIFF<1:N> are generated is because the N number of distribution variation values VA_DIFF<1:N> rather than the N number of distribution measurement values DT_DIFF<1:N> may precisely reflect the pattern in which the distribution value of the threshold voltage levels of the memory cells is changed. Namely, as described above, although the pattern in which the distribution value of the threshold voltage levels of the memory cells is changed may be precisely reflected as the preset read level interval dT is decreased, the number of operations to be performed in the memory controller 820 is increased too much when the preset read level interval dT is decreased to be too small. Thus, in the embodiment of the present invention, a method is used, where, after generating the N number of distribution measurement values DT_DIFF<1:N> by using the preset read level interval dT with a sufficiently large value, a variation in the distribution value of the threshold voltage levels of the memory cells that occurs averagely in each minimum read level interval between the N number of distribution variation values VA_DIFF<1:N> is measured through an operation of dividing the N number of distribution measurement values DT_DIFF<1:N> by ‘K’, corresponding to the minimum read level interval.

For example, referring to FIG. 7B, where ‘N’ is ‘6’ was described as an example, it may be seen that ‘PA, PB, PC, PD and PE’ as six distribution measurement values DT_DIFF<1:6> have a variation value RR higher than an actual variation value R in the threshold voltage levels of the memory cells, since counting is performed when all the memory cells with the threshold voltage levels included between the six distribution measurement values DT_DIFF<1:6> are accumulated. However, it may be seen that the variation value RR of ‘A, B, C, D and E’ as six distribution variation values VA_DIFF<1:6> generated by performing a calculation of dividing ‘PA, PB, PC, PD and PE’ as the six distribution measurement values DT_DIFF<1:6> by ‘K’ is determined when the variation value RR is approximately the actual variation value R in the threshold voltage levels of the memory cells.

Referring to FIG. 7C which is shown by enlarging the six distribution variation values VA_DIFF<1:6> of FIG. 7B, it may be seen that ‘C, D and E’ as the three distribution variation values VA_DIFF<4:6> corresponding to one direction 1 from the reference read level VRR, among ‘A, B, C, D and E’ as the six distribution variation values VA_DIFF<1:6>, are changed in their values by ‘ΔA’. Accordingly, a linear graph GRPA, which extends passing through the reference read level VRR in the one direction 1, may be drawn by assuming that the distribution value slope of the memory cells will continuously retain ‘ΔA’. Also, it may be seen that ‘C, B and A’ as the three distribution variation values VA_DIFF<3:1> corresponding to the other direction 2 from the reference read level VRR, among ‘A, B, C, D and E’ as the six distribution variation values VA_DIFF<1:6>, are changed in their values by ‘ΔB’. Accordingly, a linear graph GRPB, which extends passing through the reference read level VRR in the other direction 2, may be drawn by assuming that the distribution value slope of the memory cells will continuously retain ‘ΔB’. By determining the Interval between read levels +MAX and −MAX corresponding to the level value intercepts of the linear graphs GRPA and GRPB drawn in this way, as the recovery read level interval SAS_VRR, it may be mentioned that a variation in the distribution value of the threshold voltage levels of the memory cells is reflected on the recovery read level interval SAS_VRR.

The signal generation unit 824 generates the level control signal LV_CON with a value for controlling the normal data NM_DATA to be read from the read operation unit 804, outside the error correcting operation mode ERM, and generates the level control signal LV_CON with a value for controlling the N number of distribution data DT_DATA<1:N> or the N number of measurement data RT_DATA<1:N> to be read from the read operation unit 804, during the error correcting operation mode ERM. In other words, the signal generation unit 824 serves to control the value of the level control signal LV_CON and determine which read voltage is to be used when reading data from the memory block 801. The level control signal LV_CON may be a signal which includes plural-bit information according to the magnitude of ‘N’.

The second storage unit 827 stores the N number of distribution variation values VA_DIFF<1:N>. In other words, the second storage unit 827 stores the N number of distribution variation values VA_DIFF<1:N> which should retain their values during the operation of the first calculation unit 821 and the operation of the second calculation unit 823.

The first calculation unit 821 reads the respective N number of distribution measurement values DT_DIFF<1:N> stored in the first storage unit 808 of the nonvolatile memory device 800, performs calculations of dividing the N number of distribution measurement values DT_DIFF<1:N> by the minimum read level interval of K times for comparting the preset read level interval dT, and stores the N number of distribution variation values VA_DIFF<1:N> generated by the calculations, in the second storage unit 827.

The second calculation unit 823 reads the respective N number of distribution variation values VA_DIFF<1:N> stored in the second storage unit 827, calculates the variations of the values, generates a linear equation, finds read levels corresponding to level value intercepts in both directions from the reference read level VRR by using the linear equation generated by the calculations, and determines the interval between the two found read levels, as the recovery read level interval SAS_VRR.

The error correcting operation unit 822 detects whether an error occurs in the normal data NM_DATA and determines whether to enter the error correcting operation mode ERM, outside the error correcting operation mode ERM. In detail, the error correcting operation unit 822 performs an operation of detecting whether an error occurs in the normal data NM_DATA read from the nonvolatile memory device 800 outside the error correcting operation mode ERM. When an error occurs, the error correcting operation unit 822 enters the error correcting operation mode ERM, and when an error has not occurred, the error correcting operation unit 822 continuously retains the state exited from the error correcting operation mode ERM. A reference for determining that an error occurs in the normal data NM_DATA corresponds to when an error incapable of being immediately corrected in the error correcting operation unit 822 occurs. For example, when assuming that the normal data NM_DATA is 16-bit data, since an error up to 2 bits among the 16-bit data may be immediately corrected by the error correcting operation unit 822 through a simple operation such as a parity checking scheme, it is not determined that an error occurs. Nevertheless, since it may be impossible to immediately correct an error exceeding 3 bits, it is determined that an error occurs. Additionally, a reference by which the error correcting operation unit 822 determines the occurrence of an error may be changed in a variety of ways.

The error correcting operation unit 822 recovers the normal data NM_DATA in which an error occurs, based on the recovery read level interval SAS_VRR determined by the second calculation unit 823, during the error correcting operation mode ERM. That is to say, the error correcting operation unit 822 receives the recovery read level interval SAS_VRR determined by the second calculation unit 823, as the read interval of an LLR, during the error correcting operation mode ERM, performs an LDPC for the normal data NM_DATA in which an error occurs, and recovers the value of the normal data NM_DATA. Therefore, the error correcting operation unit 822 may perform the LDPC and recover the normal data NM_DATA, when information with a threshold voltage level distribution of the memory cells included in the nonvolatile memory device 800 is reflected on the read interval of the LLR.

As is apparent from the above descriptions, according to the embodiments of the present invention, a scheme is used where, when an error occurs in the process of reading the data stored in a plurality of memory cells by using a reference read level, distribution values of threshold voltage levels of the memory cells are respectively measured at a plurality of distribution read levels, which have a preset read level interval with the reference read level serving as a center, and a most optimized read point needed to recover data by calculating the variations of a plurality of measured distribution values by using a linear equation.

Through this, it may be possible to quickly find a read point most optimized to recover data, after a read operation in which an error occurs.

Due to this fact, high data reliability may always be achieved and it may be possible to prevent performance deterioration from occurring due to a data recovery operation, regardless of influences from surrounding environment, such as variations in PVT (i.e., process, voltage and temperature), the method used and the duration of use.

Although various embodiments have been described for illustrative purposes, it will be apparent to those skilled in the art that various changes and modifications may be made without departing from the spirit and scope of the invention as defined in the following claims.

For example, it was described as an example in the above embodiments that each of a plurality of memory cells is a single level cell (SLC) capable of storing 1-bit data. However, it is to be noted that this is merely an example, and the scope of the present invention is meant to cover when the memory cells are multi-level cells (MLC) capable of storing 2 or more-bit data.

What is claimed is:

1. A nonvolatile memory system comprising:
a nonvolatile memory device including a plurality of memory cells; and
a memory controller suitable for recovering normal data based on a recovery read level interval when an error occurs in the normal data read from the memory cells by using a reference read level,
wherein the memory controller generates N distribution measurement values by measuring distribution values of threshold voltage levels of the memory cells at N distribution read levels, which have a preset read level interval with the reference read level serving as a center, and determines the recovery read level interval through calculating variations of the N distribution measurement values by using a linear equation, where ‘N’ is a natural number equal to or greater than 2.

2. The nonvolatile memory system according to claim 1, wherein the memory controller receives the recovery read level interval, as a read interval of a log likelihood ratio (LLR), and performs a low density parity check (LDPC) for the normal data to recover the normal data.

3. The nonvolatile memory system according to claim 1, wherein the preset read level interval corresponds to K times a minimum read level interval that is controllable to read data stored in the memory cells, where ‘K’ is a natural number equal to or greater than 2.

4. The nonvolatile memory system according to claim 3, wherein the memory controller, during an error correcting operation mode, alternately reads N distribution data and N measurement data from the memory cells by alternately using the N distribution read levels and N measurement read levels, which are respectively close to the N distribution read levels with the minimum read level interval, compares the N distribution data and the N measurement data to generate differences thereof as the N distribution measurement values.

5. The nonvolatile memory system according to claim 4, wherein the memory controller, during the error correcting operation mode, generates N distribution variation values by dividing the respective N distribution measurement values by the minimum read level interval of K times for comparting the preset read level interval, and determines an interval between read levels corresponding to level value intercepts in both directions from the reference read level serving as a center, as the recovery read level interval, by extending variations of the respective N distribution variation values by using a linear equation.

6. The nonvolatile memory system according to claim 5, further comprising:
a read operation unit suitable for generating the reference read level, the N distribution read levels or the N measurement read levels based on a level control signal, and reading the data of the memory cells by using the read levels as a reference.

7. The nonvolatile memory system according to claim 6, wherein the memory controller includes:
a signal generation unit suitable for generating the level control signal with a value for controlling the normal data read from the read operation unit, outside the error correcting operation mode, and generating the level control signal with a value for controlling the N distribution data or the N measurement data read from the read operation unit, during the error correcting operation mode;
a counting unit suitable for counting differences of the N distribution data and the N measurement data to generate the N distribution measurement values, during the error correcting operation mode;
a storage unit suitable for storing the N distribution measurement values and the N distribution variation values;
a first calculation unit suitable for reading the respective N distribution measurement values stored in the storage unit, performing calculations of dividing the respective N distribution measurement values by the minimum read level interval of K times for comparting the preset read level interval, and storing the N distribution variation values generated by the calculations, in the storage unit;
a second calculation unit suitable for reading the respective N distribution variation values stored in the storage unit, generating the linear equation by calculating variations of the respective N distribution variation values, finding the read levels corresponding to the level value intercepts by using the linear equation, and determining the interval between the two found read levels, as the recovery read level interval; and
an error correcting operation unit suitable for detecting, outside the error correcting operation mode, whether an error occurs in the normal data, and determining whether to enter the error correcting operation mode, and recovering, during the error correcting operation mode, the normal data based on the recovery read level interval.

8. The nonvolatile memory system according to claim 7, wherein the storage unit includes:
N first storages for storing the respective N distribution measurement values; and
N second storages for storing the respective N distribution variation values.

9. The nonvolatile memory system according to claim 7, wherein the storage unit includes N storages suitable for storing the respective N distribution measurement values based on an operation result of the counting unit, and storing the respective N distribution variation values based on an operation result of the first calculation unit.

10. A nonvolatile memory system comprising:
a nonvolatile memory device suitable for generating N distribution measurement values by measuring distribution values of threshold voltage levels of a plurality of memory cells, by respectively using N distribution read levels, which have a preset read level interval with a reference read level serving as a center, during an error correcting operation mode, where ‘N’ is a natural number equal to or greater than 2; and
a memory controller suitable for determining to enter the error correcting operation mode when an error occurs in normal data read from the memory cells by using the reference read level, outside the error correcting operation mode, and recovering the normal data based on a recovery read level interval determined through calculating variations of the respective N distribution measurement values by using a linear equation, during the error correcting operation mode.

11. The nonvolatile memory system according to claim 10, wherein the memory controller receives the recovery read level interval, as a read interval of an LLR, and performs an LDPC for the normal data to recover the normal data.

12. The nonvolatile memory system according to claim 10, wherein the preset read level interval corresponds to K times a minimum read level interval that is controllable to read data stored in the memory cells, where ‘K’ is a natural number equal to or greater than 2.

13. The nonvolatile memory system according to claim 12, wherein the nonvolatile memory device, during the error correcting operation mode, alternately reads N distribution data and N measurement data from the memory cells by alternately using the N distribution read levels and N measurement read levels, which are respectively close to the N distribution read levels with the minimum read level interval, and compares the N distribution data and the N measurement data to generate differences thereof as the N distribution measurement values.

14. The nonvolatile memory system according to claim 13, wherein the memory controller, during the error correcting operation mode, generates N distribution variation values by dividing the respective N distribution measurement values by the minimum read level interval of K times for comparting the preset read level interval, during the error correcting operation mode, and determines an interval between read levels corresponding to level value intercepts in both directions from the reference read level, as the recovery read level interval, by extending variations of the respective N distribution variation values by using the linear equation.

15. The nonvolatile memory system according to claim 14, wherein the nonvolatile memory device includes:
a read operation unit suitable for generating the reference read level, the N distribution read levels or the N measurement read levels based on a level control signal, and reading the data of the memory cells, based on using the read levels as a reference;
a counting unit suitable for counting differences of the N distribution data and the N measurement data to generate the N distribution measurement values, during the error correcting operation mode; and
a first storage unit suitable for storing the N distribution measurement values.

16. The nonvolatile memory system according to claim 15, wherein the memory controller includes:
a signal generation unit suitable for generating the level control signal with a value for controlling the normal data read from the read operation unit, outside the error correcting operation mode, and generating the level control signal with a value for controlling the N distribution data or the N measurement data read from the read operation unit, during the error correcting operation mode;
a second storage unit suitable for storing the N distribution variation values;
a first calculation unit suitable for reading the respective N distribution measurement values stored in the first storage unit, performing calculations of dividing the respective N distribution measurement values by the minimum read level interval of K times for comparting the preset read level interval, and storing the N distribution variation values generated by the calculations, in the second storage unit;
a second calculation unit suitable for reading the respective N distribution variation values stored in the second storage unit, generating the linear equation, finding the read levels corresponding to the level value intercepts by using the linear equation generated, and determining the interval between the two found read levels, as the recovery read level interval; and
an error correcting operation unit suitable for detecting, outside the error correcting operation mode, whether an error occurs in the normal data, and determining whether to enter the error correcting operation mode, and recovering, during the error correcting operation mode, the normal data based on the recovery read level interval.

17. A data recovery method of a nonvolatile memory system including a plurality of memory cells, the method comprising:
generating N distribution measurement values by measuring distribution values of threshold voltage levels of the memory cells, by respectively using N distribution read levels, which have a preset read level interval with a reference read level serving as a center, during an error correcting operation mode, where ‘N’ is a natural number equal to or greater than 2;
determining to enter the error correcting operation mode when an error occurs in normal data read from the memory cells by using the reference read level, outside the error correcting operation mode; and
recovering the normal data based on a recovery read level interval determined through calculating variations of the respective N distribution measurement values by using a linear equation, during the error correcting operation mode.

18. The data recovery method of according to claim 17, wherein the recovering of the normal data includes:
performing an LDPC for the normal data by using the recovery read level interval as a read interval of an LLR.

19. The data recovery method of according to claim 17, wherein the preset read level interval corresponds to K times a minimum read level interval that is controllable to read data stored in the memory cells, where ‘K’ is a natural number equal to or greater than 2.
